(19) United States
(12) Patent Application Publication
(10) Pub. No.: US 2014/0103323 A1
(43) Pub. Date: Apr. 17, 2014

(54) ORGANIC COMPONENT COMPRISING ELECTRODES HAVING AN IMPROVED LAYOUT AND SHAPE

(71) Applicant: Mohammed Benwadih, Champigny Sur Marne (FR)

(72) Inventor: Mohammed Benwadih, Champigny Sur Marne (FR)

(73) Assignees: ISORG, Grenoble (FR); Commissariat a l'energie atomique et aux ene alt, Paris (FR)

(21) Appl. No.: 14/123,117

(22) PCT Filed: May 30, 2012
(86) PCT No.: PCT/EP2012/060144

§ 371 Date: Nov. 29, 2013

(30) Foreign Application Priority Data
Jun. 1, 2011 (FR) 11 54828

(51) Int. Cl. H01L 51/10; H01L 51/44

(52) U.S. Cl. CPC H01L 51/105; H01L 51/441
USPC 257/40

(57) ABSTRACT

A component with organic active material including at least one first electrode and at least one second electrode, the first electrode and the second electrode being separated by a region of an active layer based on a polymer material, the region of the active layer separating the electrodes having a variable critical dimension.

### TECHNICAL FIELD

The present invention relates to the field of components provided with an active area based on a semiconductor polymer material situated between two electrodes, in particular that of so-called “organic” transistors and photodiodes.

It provides a microelectronic component the electrodes of which have a form and arrangement improving its performance in particular in terms of ratio between its current in the ON state or in its functioning state and its current in the OFF state or in its non-operating state.

### PRIOR ART

An example of a field effect organic transistor used according to the prior art is given in FIGS. 1A-1B.

The transistor comprises an active layer 2 resting on a support 1 and covering two source and drain electrodes 4 and 6.

The active layer 2 is formed from a material of the organic polymer type, having semiconductor properties. This transistor is arranged so that its gate electrode 10 is placed on top of the source 4 and drain 6 electrodes (FIG. 1A).

The electrodes 4 and 6 are in the form of parallelepipedal blocks and thus comprise two injection surfaces Si1 and Si2 carrying charges in or from the channel area 3, a first injection surface Si1 corresponding to a face of the electrode blocks that is parallel to the principal plane of the active layer 2 and in contact with the latter, and another face of the electrode block that is orthogonal to the principal plane of the active layer 2 and in contact with the latter.

The Ion/Ioff ratio is the ratio that characterises the ON state and the OFF state of a transistor. The Ioff current is the leakage current, which it is sought to minimise, while the Ion current is the saturation current at a given gate source voltage that it is sought to make maximum.

It is sought in general terms to use organic components having a ratio between current in the ON state or in the active state and current in the OFF state or the inactive state that is as high as possible.

### DISCLOSURE OF THE INVENTION

The invention concerns first of all a microelectronic component, in particular organic, provided with at least one first electrode and at least one second electrode, the first electrode and the second electrode being separated by a region of an active layer based on at least one polymer material, in particular semiconductive, the first electrode and the second electrode having a form and arrangement designed so that the distance separating them varies.

Thus the region of the active layer separating the first electrode and the second electrode has a length, also referred to as the “critical dimension” D_{L}, that is variable.

“Critical dimension” means here the smallest dimension of a layer or stack of layers apart from its thickness.

According to a first aspect of the invention, the component may be a transistor, in particular an organic transistor.

In this case, said first electrode may be a source electrode, while the second electrode may be a drain electrode, the transistor also comprising a gate electrode opposite said region of polymer material separating said first electrode and second electrode and at least one portion of the source and drain electrodes.

The source electrode and/or the drain electrode may be provided respectively with an inclined flank producing a non-zero angle with the principal plane of the active layer.

The source and drain electrodes may be disposed on a substrate and surmounted by the gate electrode. According to a particular arrangement, the gate electrode may advantageously be situated opposite only a portion of the source and drain electrodes.

Thus a portion of the source and drain electrodes situated close to the channel area of the transistor may be disposed opposite the gate electrode, while other areas of the source and drain electrode are not surmounted by the gate electrode and are not situated opposite the gate electrode.

According to one arrangement possibility, the source electrode and the drain electrode may have a form such that the distance separating the first electrode and the second electrode varies linearly or substantially linearly.

The arrangement of the source and drain electrodes may also be designed so that the distance separating the source electrode and the drain electrode increases as the gate electrode is approached.

This improves the transistor in terms of saturation current Ion while having a reduced leakage current Ioff.

The source electrode and the drain electrode may have the form of a prism with triangular bases, the triangular bases being orthogonal to the active layer or to the principal plane of the active layer.

According to another implementation possibility, the transistor may be formed so that the distance separating the source electrode and the drain electrode increases in a direction parallel to the gate electrode and to the active layer.

The source electrode and the drain electrode may have the form of a prism with triangular bases parallel to the principal plane of the active layer.

According to a second aspect of the invention, the component may be a diode, in particular a photodiode.

According to one implementation possibility, the first electrode and/or the second electrode may be provided with an inclined flank making an angle with the principal plane of the active layer.

The first electrode and the second electrode may have a form such that the distance separating the first and second electrode varies linearly.

According to one implementation possibility, the first electrode and the second electrode may have the form of a prism with triangular bases, the triangular bases making a non-zero angle with the active principal plane.

According to one implementation possibility, the first electrode and the second electrode may be provided respectively with a first inclined flank making a non-zero angle with the principal plane of the active layer, as well as a second inclined flank opposite said first flank and making a non-zero angle with a principal plane of the active layer, the first flank and the second flank being provided with services reflecting light radiation.

### BRIEF DESCRIPTION OF THE DRAWINGS

The present invention will be understood better from a reading of the description of example embodiments given purely by way of indication and in no way limitatively, referring to the accompanying drawings, wherein:

FIGS. 1A and 1B illustrate a field effect organic transistor according to the prior art,

FIGS. 2A-2D illustrate an example of a field effect organic transistor implemented according to the invention, wherein the arrangement and form of the electrodes is improved,

FIG. 3 illustrates another example of a field effect organic transistor implemented according to the invention, wherein the arrangement and form of the electrodes is improved,

FIG. 4 illustrates an organic photodiode implemented according to the invention, provided with electrodes with improved arrangement and form,

FIGS. 5A-5B illustrate a method for producing electrodes of an organic component implemented according to the invention.

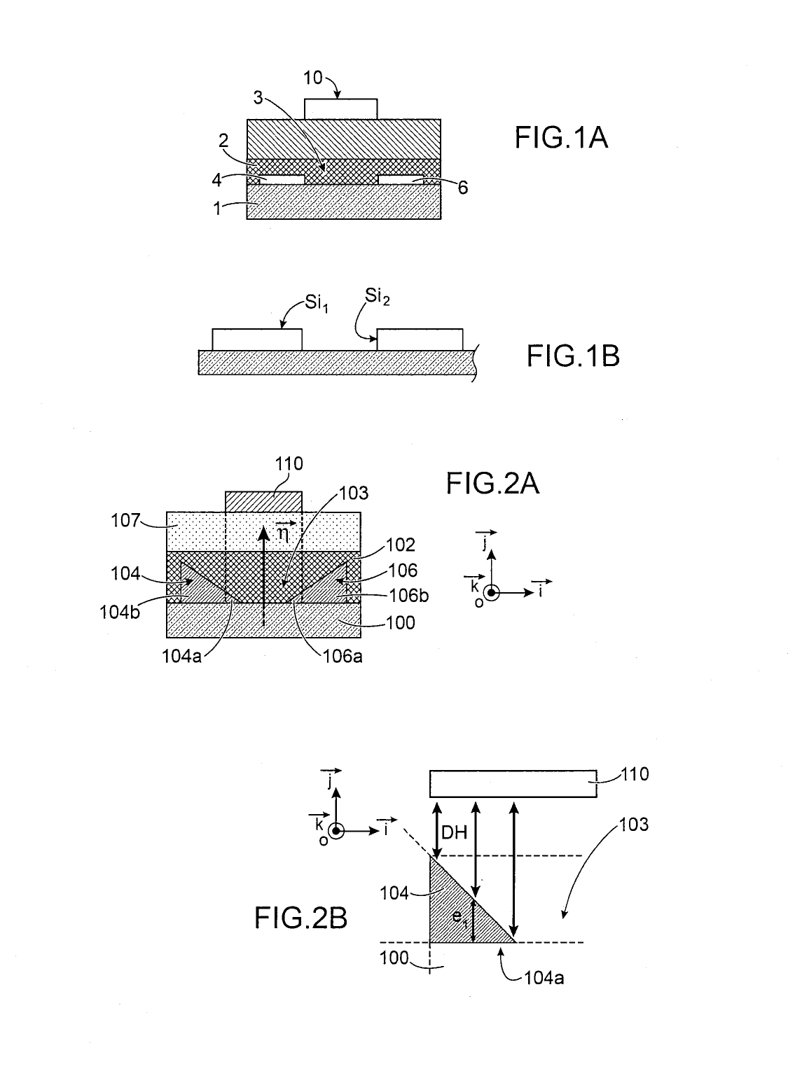

Identical, similar or equivalent parts in the various figures bear the same numerical references so as to facilitate passing from one figure to another.

The various parts shown in the figures are not necessarily shown to a uniform scale, in order to make the figures more legible.

### DETAILED DISCLOSURE OF PARTICULAR EMBODIMENTS

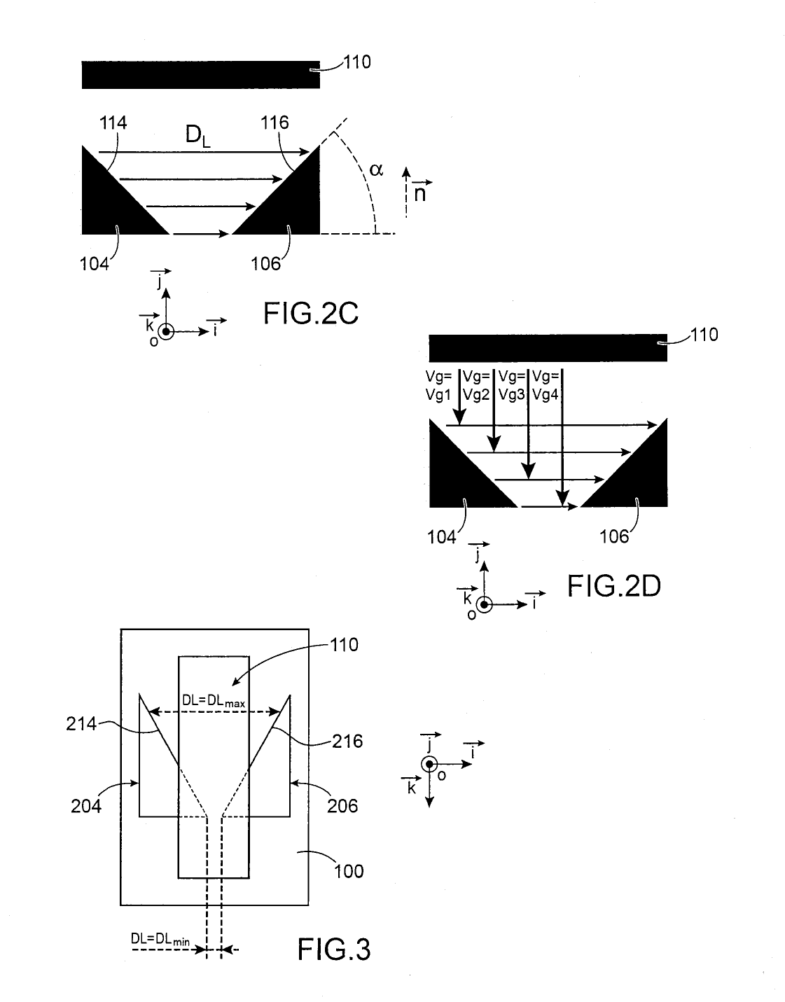

An example of a microelectronic component according to the invention will now be described in relation to FIGS. 2A-2D.

The microelectronic component is, in this example, a field effect organic transistor, formed on a support 100, for example based on polyethylene naphthalate and with a thickness of between for example 50 μm and 200 μm, advantageously between 100 μm and 150 μm.

An active layer 102 based on at least one semiconductor polymer material, for example such as TIPS (triisopropylsilyl pentacene) and for example between 20 nanometres and 200 nanometres thick, rests on the substrate 100.

This active layer 102 comprises an area 103 forming a channel and situated between two source and drain electrodes 104 and 106, opposite a gate electrode 110.

The source 104 and drain 106 electrodes rest on the support 100 and are covered by the active layer 102. The source 104 and drain 106 electrodes may have a thickness varying from 20 to 200 nanometres.

In this example embodiment, the electrodes 104, 106 are surmounted by a thickness of the active layer 102, this thickness of the active layer 102 being itself surmounted by a dielectric gate layer 107, for example a layer based on fluorinated polymer or polystyrene, for example Cytop® from the company Asahi Glass and for example between 400 nanometres and 1 micrometre thick, while the gate electrode 110 rests on the layer of dielectric 107, and is thus situated on top of the source 102 and drain 104 electrodes.

The gate electrode 110 is disposed opposite a region 103 of the active layer and a portion 104a of the source electrode 104 and a portion 104b of the drain electrode 106.

Thus in this example only the portions 104a and 106a of the source and drain electrodes are surmounted by the gate electrode 110 and opposite this gate electrode 110. Other areas 104b, 106b of the electrodes 104, 106 further away from the channel area of the transistor than the portions 104a and 106a and closer to the gate dielectric area 107 than the portions 104a, 106a are for their part not disposed opposite the gate electrode 110.

This gate electrode 110 may be formed for example from Ag and be for example between 100 nanometres and 5 micrometres thick (FIG. 2A).

In this transistor, the distance D_{L} separating the source electrode 104 and the drain electrode 106 is designed so as to be variable depending on whether one is situated in a region situated between them.

The arrangement of the electrodes may be designed in particular so that the distance D_{L} separating the source electrode 104 and the drain electrode 106 varies linearly.

In the example in FIG. 2B, an electrode of the transistor, for example its source electrode 104, has a variable thickness eₗ measured in a direction orthogonal to the principal plane of the active layer 102 (the principal plane of the active layer 102 being the plane defined as passing through this layer and parallel to the plane [o; \vec{i}; \vec{k}] of the orthogonal reference frame [o;\vec{i};\vec{j};\vec{k}] in FIGS. 2A-2D).

The distance D_{H} (measured in a direction parallel to the vector \vec{j} of the orthogonal reference frame [o;\vec{i};\vec{j};\vec{k}] separating the gate electrode 110 from this source electrode 104 is thus variable and increases as the centre of the region 103 situated between the source and drain electrodes 104 and 106 (FIG. 2B) is approached.

In the example in FIG. 2C, it is the two source and drain electrodes 104 and 106 that have a variable thickness and are arranged so that the distance D_{L} (measured in a direction parallel to the vector i of the orthogonal reference frame [o;\vec{i};\vec{j};\vec{k}] separating these electrodes 104, 106 is variable and increases as the gate electrode 110 is approached.

In this example embodiment, the electrodes 104 and 106 are provided with inclined flanks and comprise respectively a first inclined flank 114 and second inclined flank 116 situated opposite the first flank 114.

Each of the flanks 114 and 116 makes a non-zero angle with a normal n to the principal plane of the substrate 100 or of the active layer 102 or an angle α of less than 90° with a plane parallel to the principal plane of the substrate 100 or of the active layer 102.

The angle α made between each of the flanks 114 and 116 and the principal plane of the substrate 100 or of the active layer 102 may for example be between 15° and 85°, in particular between 30° and 60°, and for example 45°.

The source 104 and drain 106 electrodes thus have, in this example, the form of a prism, provided with triangular bases forming a non-zero angle, for example 90°, with the principal plane of the substrate 100 or of the active layer 102.

In this example embodiment, when the gate 110 is biased at a gate potential Vg, the semiconductor material of the layer 102 is depleted to a certain depth. Charges are then subjected to an electrical field created between the electrodes 104 and 106 by the application of a drain-source voltage VDS and constitute the response of the transistor in the form of a current.

For a low gate potential Vg=vg1, only the upper part of the active layer based on semiconductor polymer is depleted. This upper part of the active layer corresponds to the place where the distance D_{L} between the electrodes 104 and 106 is the greatest.

Thus, for a given drain-source voltage VDS, the electrical field created is weak, so that there are few charges collected and therefore a very low current Ioff or the transistor in the OFF state.

On the other hand, for a high gate potential Vg=Vg4, the depleted area is deeper where the distance D_{L} between electrodes is the smallest. A maximum amount of charges is then collected since the electrical field is the strongest, the current in the ON state Ion is higher (FIG. 2D).

A transistor provided with a structure may thus have both an increased current Iₒₙ in the ON state and a reduced current ‘_{off} in the OFF state compared with an organic transistor structure having a conventional arrangement of electrodes.

Another example of a field effect organic transistor according to the invention is given in FIG. 3 (the transistor being shown in plan view in this figure).

This transistor comprises a source electrode 204 and a drain electrode 206 separated by a variable distance DL, and differs from the one described previously through the form of its source 204 and drain 206 electrodes.

The source 204 and drain 206 electrodes are, in this example, plates in the form of prisms with triangular bases, the bases of the prisms being parallel to the principal plane of the active layer 102 or of the support layer 100 (the principal plane of the active 102 being a plane parallel to the plane [o;\vec{i};\vec{k}] given in FIG. 3).

The source and drain electrodes 204 and 206 are arranged so that the distance D_{L} (measured in a direction parallel to the vector \vec{i} of the orthogonal reference frame [o;\vec{i};\vec{j};\vec{k}] separating these electrodes 204 and 206 varies linearly, so that, when a voltage is applied between the electrodes 204, 206 the electrical field between the electrodes varies along the gate at (in a direction parallel to the vector \vec{k} of the orthogonal reference frame [o;\vec{i};\vec{j};\vec{k}].

In this example, the distance D_{H} (measured in a direction parallel to the vector \vec{j} and which is not shown in FIG. 3) separating each source 204 or drain 206 electrode from the gate electrode 210, may be constant.

In this example, whatever the voltage applied to the gate 210, the same volume of semiconductor organic material situated between the electrodes is depleted. The electrical field created by the source and drain voltage VDS is however not constant over the entire length of the transistor or along the gate (in a direction parallel to the vector \vec{k} of the orthogonal reference frame [o;\vec{i};\vec{j};\vec{k}]).

A source-drain voltage VDS=VDS2 may be used in an area where the spikes 217, 218 of the electrodes are situated opposite each other at a distance DL-DLmin from each other, while a voltage VDS=VD1, which is lower, is used in an area situated between the electrodes 204 and 206, where the separation between the latter is the greatest.

Because of the variable separation between the electrodes 204 and 206 in the direction of the length of the transistor, these electrodes 204 and 206 may be spaced apart by a minimal distant DLmin that may be less than the minimum separation generally provided for the electrodes of organic transistors.

The variable separation between the electrodes 204 and 206 thus makes it possible to limit the tunnel effect and to have electrodes closer together.

The minimum separation at the point where the spikes of the electrodes are opposite may be at least less than 10 μm and for example around 5 μm. The electrodes 204 and 206 may be spaced apart by a maximum distance DLmax, for example around 55 μm. Such an arrangement makes it possible to obtain a current Ion in the ON state that is greater than that of a conventional transistor the electrodes of which are arranged at a constant separation, for example around 30 μm.

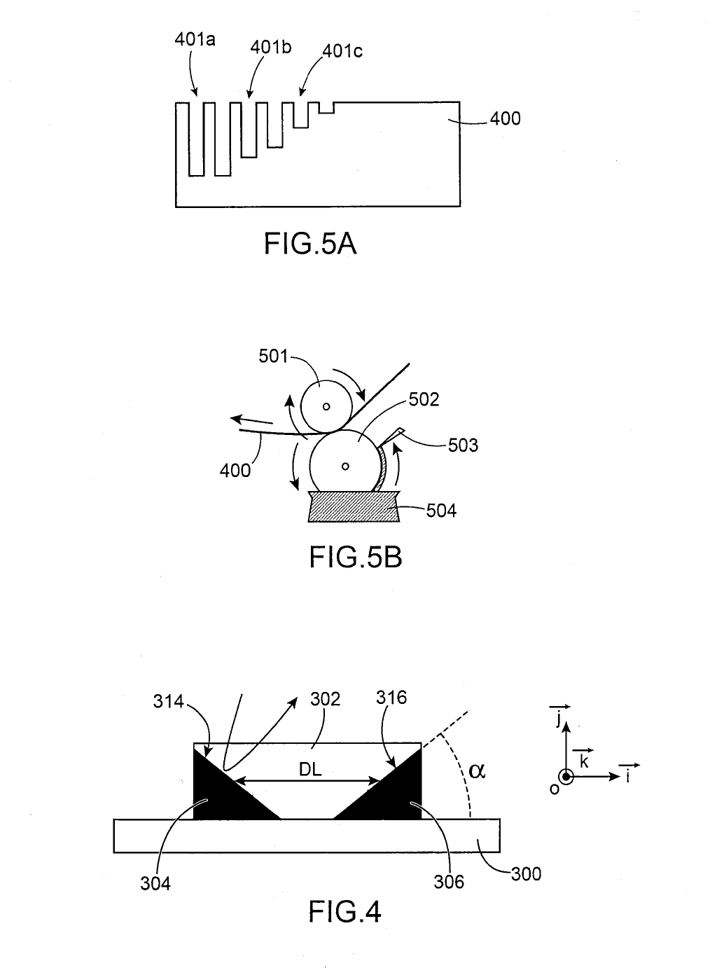

Another example of a microelectronic component according to the invention, provided with an active area based on polymer, is given in FIG. 4.

In this example, the component is an organic photodiode comprising electrodes 304 and 306 resting on a support 300, and an active layer 302 situated between the electrodes.

The active layer 302 may be based on a mixture of polymer materials, comprising an n-type semiconductor polymer material and a p-type semiconductor polymer material.

The polymer material of the active layer 302 may be a mixture of a p-type polymer such as for example poly(3-hexylthiophene) or poly(3-hexylthiophene-2,5-diyl) and commonly referred to as “P3HT”, and an N-type polymer such as for example methyl[6,6]-phenyl-C₆₁-butanoate and commonly referred to as “PCBM”.

The active layer 302 may have a thickness of between for example 50 and 400 nanometres.

The electrodes 304 and 306 are in this example in the form of prisms with triangular bases, the triangular bases making a non-zero angle, for example 90°, with the principal plane of the support layer or the principal plane of the active layer 302 (the principal plane of the active layer 302 being a plane parallel to the plane [o;\vec{i};\vec{k}] given in FIG. 4).

The source and drain electrodes 304 and 306 are arranged so that the distance D_{L} (measured in a direction parallel to the vector \vec{i} of the orthogonal reference frame [o;\vec{i};\vec{j};\vec{k}]) separating these electrodes 304 and 306 is variable, and increases, in particular linearly, on moving away from the support 300.

In this example embodiment, the electrodes 304 and 306 of the photodiode are provided with inclined flanks with a reflective surface and comprise respectively a first inclined flank 314 with a reflective surface and a second inclined flank 316 with a reflective surface situated opposite the first inclined flank 314.

The flanks 314 and 316 make a non-zero angle α, for example between 30° and 60°, for example 45°, with the principal plane of the support 300 or of the active layer 302, and are intended to reflect a light radiation that has passed through the active layer 302. In this way the quantity of excitons generated in the material of the active layer 302 can be increased.

The electrodes 304 and 306 may for example be based on gold and have a thickness varying from 20 nanometres to 200 nanometres.

Under low illumination, charges may be created in an upper area of the active layer 302, in regions where the spacing DL between the electrodes 304 and 306 is the greatest and equal to DLmax, for example around 10 micrometres to 500 micrometres.

Under strong illumination, excitons may be formed throughout the thickness of the active area 302.

In regions of the active area 302 where the width is small, there will be many more charges collected: the illumination will be higher.

By being provided also with reflective surfaces 314, 316, the electrodes may fulfil a role of optical reflectors and redirect photons towards the inside of the active area 302 in order to increase the number of charges collected.

The electrodes 304 and 306 may be formed for example from Au and be covered with a reflective surface base on a layer of Ag.

An example embodiment of electrodes with inclined flanks and intended to be integrated in a microelectronic component with organic active material will now be given in relation to FIGS. 5A-5B.

A mask 400 from which these electrodes are produced may for example be polyethylene naphthalate.

A series of holes 401a, 401b, 401c with different decreasing depths are formed in this support, which are filled with a conductive ink, for example such as an ink containing gold or silver nanoparticles.

The method may be implemented by photogravure with a device provided with a pressing cylinder 501 and an engrave cylinder between which the mask 400 to be printed is passed in order to form the holes 401a, 401b, 401c, the engraved cylinder passing through an ink duct 504 filled with conductive ink. The photogravure device may be provided with means for removing the surplus ink. Then the pattern formed is removed from the mould and transferred to the final electrode support.

According to another method, the mask may be filled with a polymer that is then removed from the mould and serves as a support for the deposition of a conductive layer.

1-14. (canceled)

15. A microelectronic component comprising:
at least one first electrode and at least one second electrode;
the first electrode and the second electrode being separated by a region of an active layer based on at least one semiconductor polymer material, the region of the active layer separating the electrodes having a variable critical dimension,
the first electrode and the second electrode having a form of a prism with triangular bases orthogonal to the principal plane of the layer of polymer material.

16. A microelectronic component according to claim 15, the first electrode being a source electrode, the second electrode being a drain electrode, and further comprising a gate electrode opposite the region of semiconductor polymer material separating at least one portion of the source and drain electrodes.

17. The microelectronic component according to claim 16, the source electrode or the drain electrode or both source and drain electrodes including at least one inclined flank making a non-zero angle with the principal plane of the active layer.

18. The transistor according to claim 17, the source electrode and the drain electrode having a form such that a distance separating the first electrode and the second electrode varies linearly.

19. The transistor according to claim 18, the distance separating the source electrode and the drain electrode increasing as the gate electrode is approached.

20. The transistor according to claim 19, wherein the gate electrode surmounts and is situated opposite a given portion of the source electrode and a given portion of the drain electrode, other portions of the source electrode and drain electrode not being situated opposite the gate electrode.

21. The transistor according to claim 16, the source electrode and the drain electrode having a form of a prism with triangular bases orthogonal to the principal plane of the layer of polymer material.

22. The transistor according to claim 16, the distance separating the source electrode and the drain electrode increasing in a direction parallel to the principal plane of the active layer.

23. The transistor according to claim 22, the source electrode and the drain electrode having a form of a prism with triangular bases parallel to the principal plane of the layer of polymer material.

24. The photodiode according to claim 15, the first electrode or the second electrode or both the first electrode and the second electrode including an inclined flank making a non-zero angle with the principal plane of the active layer.

25. The photodiode according to claim 24, the first electrode and the second electrode having a form such that the distance separating the first electrode and the second electrode varies linearly.

26. The photodiode according to claim 24, the first electrode and the second electrode having a form of a prism with triangular bases, the triangular bases making a non-zero angle with the active principal plane.

27. The photodiode according to claim 24, the first electrode and the second electrode including respectively a first inclined flank making a non-zero angle with the principal plane of the active layer, and a second inclined flank opposite the first flank and making a non-zero angle with the principal plane of the active layer, the first flank and the second flank having surfaces reflecting light radiation.
